(19) United States
(12) Patent Application Publication
(10) Pub. No.: US 2019/0035607 A1
(43) Pub. Date: Jan. 31, 2019

(54) SUBSTRATE PROCESSING APPARATUS

(71) Applicant: JUSUNG ENGINEERING CO., LTD., Gwangju-si, Gyeonggi-do (KR)

(72) Inventors: Se Young KIM, Gwangju-si, Gyeonggi-do (KR); Su-Young KWON, Gwangju-si, Gyeonggi-do (KR); Jin Hyuk YOO, Gwangju-si, Gyeonggi-do (KR); Byoung Ha CHO, Gwangju-si, Gyeonggi-do (KR); Min Ho CHEON, Gwangju-si, Gyeonggi-do (KR); Chul-Joo HWANG, Gwangju-si, Gyeonggi-do (KR)

(21) Appl. No.: 16/073,318

(22) PCT Filed: Jan. 24, 2017
(86) PCT No.: PCT/KR2017/000796

§ 371 Date: Jul. 26, 2018

(30) Foreign Application Priority Data
Jan. 26, 2016 (KR) 10-2016-0009527
Jan. 13, 2017 (KR) 10-2017-0005856

(51) Int. Cl. H01J 37/32; H01L 21/3065; H01L 21/687; H01L 21/67; H01L 21/673

(52) U.S. Cl. CPC H01J 37/32449; H01L 21/3065; H01J 37/32174; H01L 21/67161; H01L 21/67309; H01L 21/68714

(57) ABSTRACT

The present disclosure relates to a substrate processing apparatus, to which a source gas and a reactant gas are distributed, including a first exhaust line exhausting a first exhaust gas including the reactant gas and the source gas which is more than the reactant gas, a second exhaust line exhausting a second exhaust gas including the source gas and the reactant gas which is more than the source gas, a catch device installed in the first exhaust line, and a third exhaust line connected to an exhaust pump to exhaust the first exhaust gas passing through the catch device and the second exhaust gas passing through the second exhaust line.

### TECHNICAL FIELD

The present disclosure relates to a substrate processing apparatus for depositing a thin film on a substrate.

### BACKGROUND ART

Generally, a thin-film layer, a thin-film circuit pattern, or an optical pattern should be formed on a substrate surface for manufacturing a solar cell, a semiconductor device, a flat panel display device, etc. To this end, a semiconductor manufacturing process is performed, and examples of the semiconductor manufacturing process include a thin film deposition process of depositing a thin film including a specific material on a substrate, a photo process of selectively exposing a portion of a thin film by using a photosensitive material, an etching process of removing a thin film corresponding to the selectively exposed portion to form a pattern, etc.

The semiconductor manufacturing process is performed inside a substrate processing apparatus which is designed based on an optimal environment for a corresponding process, and recently, substrate processing apparatuses for performing a deposition or etching process based on plasma are much used.

Examples of the substrate processing apparatuses based on plasma include plasma enhanced chemical vapor deposition (PECVD) apparatuses for forming a thin film by using plasma, plasma etching apparatuses for etching and patterning a thin film, etc.

FIG. 1 is a schematic side cross-sectional view of a related art substrate processing apparatus.

Referring to FIG. 1, the related art substrate processing apparatus includes a chamber 10, a plasma electrode 20, a susceptor 30, and a gas distribution means 40.

The chamber 10 provides a process space for a substrate processing process. In this case, both floor surfaces of the chamber 10 communicate with a pumping port 12 for exhausting the process space.

The plasma electrode 20 is installed on the chamber 10 to seal the process space.

One side of the plasma electrode 20 is electrically connected to a radio frequency (RF) power source 24 through a matching member 22. In this case, the RF power source 24 generates RF power and supplies the RF power to the plasma electrode 20.

Moreover, a center portion of the plasma electrode 20 communicates with a gas supply pipe 26 that supplies a source gas and a reactant gas for the substrate processing process.

The matching member 22 is connected between the plasma electrode 20 and the RF power source 24 and matches a source impedance with a load impedance of the RF power supplied from the RF power source 24 to the plasma electrode 20.

The susceptor 30 is installed in the chamber 10 and supports a plurality of substrates W loaded from the outside. The susceptor 30 is an opposite electrode opposite to the plasma electrode 20 and is electrically grounded through an elevation shaft 32 that raises and lowers the susceptor 30.

A substrate heating means (not shown) for heating the supported substrate W is built into the susceptor 30, and the substrate heating means heats the susceptor 30 to heat a bottom of the substrate W supported by the susceptor 30.

The elevation shaft 32 is raised and lowered in an up and down direction by an elevation apparatus (not shown). At this time, the elevation shaft 32 is surrounded by bellows 34 that seal the elevation shaft 32 and the floor surfaces of the chamber 10.

The gas distribution means 40 is installed under the plasma electrode 20 so as to be opposite to the susceptor 30. In this case, a gas diffusion space 42 where the source gas and the reactant gas supplied from the gas supply pipe 26 passing through the plasma electrode 20 are diffused is provided between the gas distribution means 40 and the plasma electrode 20. The gas distribution means 40 uniformly distributes the source gas and the reactant to a whole portion of the process space through a plurality of gas distribution holes 44 communicating with the gas diffusion space 42.

The related art substrate processing apparatus loads the substrate W onto the susceptor 30, heats the substrate W loaded onto the susceptor 30, distributes the source gas and the reactant gas to the process space of the chamber 10, and supplies the RF power to the plasma electrode 20 to generate plasma, thereby forming a certain thin film on the substrate W. Also, the source gas and the reactant gas which are distributed to the process space in a thin film deposition process flow to an edge of the susceptor 30 and are exhausted to outside the process chamber 10 through the pumping port 12 provided in each of the both floor surfaces of the process chamber 10.

The related art substrate processing apparatus has the following problems.

First, since the related art substrate processing apparatus forms a certain thin film on the substrate W through a chemical vapor deposition (CVD) process where the source gas and the reactant gas are mixed with each other in the process space and are deposited on the substrate, a characteristic of the thin film is non-uniform, and the quality of the thin film is difficult to control.

Second, in the related art substrate processing apparatus, the source gas and the reactant gas used in the thin film deposition process are emitted to the outside through pumping port 12 with being mixed. Therefore, in the related art substrate processing apparatus, particles having a particulate state are generated from a mixed gas in a process where the mixed gas where the source gas and the reactant gas are mixed is emitted, and for this reason, the generated particles act as a factor of obstructing smooth emission of an exhaust gas, causing the reduction in exhaust efficiency. Also, in the related art substrate processing apparatus, a time taken in exhaust increases due to the reduction in exhaust efficiency, and for this reason, a process time of the thin film deposition process is delayed.

### DISCLOSURE

### Technical Problem

Therefore, the present disclosure has been made in view of the above problems, and it is an object of the present disclosure to provide a substrate processing apparatus in which a source gas and a reactant gas are mixed in a process space, thereby solving a difficulty to control the characteristic non-uniformity of a thin film and the quality of the thin film.

The present disclosure is directed to provide a substrate processing apparatus in which a source gas and a reactant gas are emitted with being mixed, thereby preventing exhaust efficiency from being reduced due to generation of particles and preventing a process time from being delayed in a thin film deposition process.

### Technical Solution

To accomplish the above-described objects, a substrate processing apparatus according to the present disclosure, to which a source gas and a reactant gas are distributed, includes: a first exhaust line exhausting a first exhaust gas including the reactant gas and the source gas which is more than the reactant gas; a second exhaust line exhausting a second exhaust gas including the source gas and the reactant gas which is more than the source gas; a catch device installed in the first exhaust line; and a third exhaust line connected to an exhaust pump to exhaust the first exhaust gas passing through the catch device and the second exhaust gas passing through the second exhaust line, wherein the catch device catches the source gas flowing into the first exhaust line.

A substrate processing apparatus according to the present disclosure, where an area of a chamber to which a source gas is distributed differs from an area of the chamber to which a reactant gas is distributed, or the source gas and the reactant gas are distributed with a time difference, includes: a first exhaust line emitting the source gas from the chamber; a second exhaust line spaced apart from the first exhaust line to emit the reactant gas from the chamber; a first collection unit collecting a gas including the source gas flowing into the first exhaust line to process the collected gas with plasma; and a second collection unit collecting a gas including an exhaust gas flowing into the second exhaust line and a gas passing through the first collection unit.

A substrate processing apparatus according to the present disclosure, where an area of a chamber to which a source gas is distributed differs from an area of the chamber to which a reactant gas is distributed, or the source gas and the reactant gas are distributed with a time difference, includes: a first exhaust line emitting the source gas from the chamber; a second exhaust line spaced apart from the first exhaust line to emit the reactant gas from the chamber; a first collection unit collecting a gas including the source gas flowing into the first exhaust line to process the collected gas with plasma; and a second collection unit collecting a gas including an exhaust gas flowing into the second exhaust line and a mixed gas of an exhaust gas which has been plasma-activated by passing through the first collection unit.

A substrate processing apparatus according to the present disclosure, where an area of a chamber to which a source gas is distributed differs from an area of the chamber to which a reactant gas is distributed, or the source gas and the reactant gas are distributed with a time difference, includes: a first exhaust line connected to the chamber; a second exhaust line connected to and spaced apart from the first exhaust line; a plasma generator provided in the first exhaust line; and a second collection unit having a non-plasma manner, wherein a first exhaust gas passing through the plasma generator and a second exhaust gas passing through the second exhaust line are mixed and flow into the second collection unit.

A substrate processing apparatus according to the present disclosure, where an area of a chamber to which a source gas is distributed differs from an area of the chamber to which a reactant gas is distributed, or the source gas and the reactant gas are distributed with a time difference, includes: a first exhaust line connected to the chamber; a second exhaust line connected to and spaced apart from the first exhaust line; and a second collection unit having a non-plasma manner, wherein a first exhaust gas plasma-activated in the first exhaust line and a second exhaust gas passing through the second exhaust line are mixed and flow into the second collection unit.

### Advantageous Effect

According to the present disclosure, the following effects can be obtained.

The present disclosure is implemented to decrease a degree to which a source gas and a reactant gas are mixed in the middle of being distributed, thereby enhancing uniformity of the quality characteristic of a thin film and enhancing controllability of the quality of the thin film.

Since the present disclosure is implemented to decrease a degree to which the source gas and the reactant gas are mixed in the middle of being emitted, exhaust efficiency can be enhanced by preventing particles from being generated from the source gas, and moreover, a time taken in exhaust is shortened, thereby contributing to shorten a process time of a thin film deposition process.

### DESCRIPTION OF DRAWINGS

FIG. 1 is a schematic side cross-sectional view of a related art substrate processing apparatus.

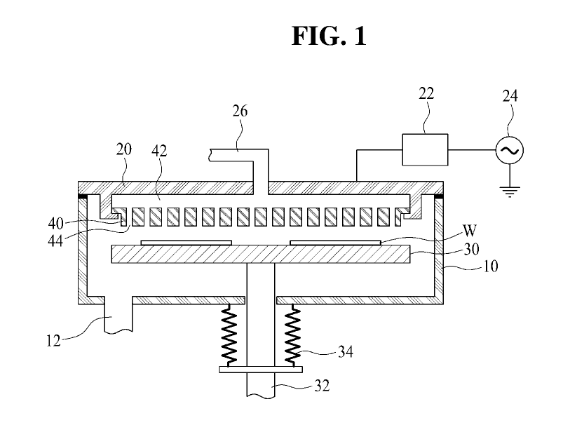

FIG. 2 is a block diagram schematically illustrating a substrate processing apparatus according to a first embodiment.

FIG. 3 is a schematic perspective view of the substrate processing apparatus according to the first embodiment.

FIG. 4 is a schematic plan view of the substrate processing apparatus according to the first embodiment.

FIG. 5 is a schematic exploded perspective view of the substrate processing apparatus according to the first embodiment.

FIG. 6 is a schematic plan view for describing an embodiment where a source gas and a reactant gas are independently emitted by using a purge gas in the substrate processing apparatus according to the first embodiment.

FIG. 7 is a schematic plan view for describing an embodiment where a source gas and a reactant gas are independently emitted by using a division member in the substrate processing apparatus according to a modified first embodiment.

FIG. 8 is a schematic exploded perspective view of a substrate processing apparatus according to another modified first embodiment.

FIG. 9 is a schematic plan view for describing an embodiment where a source gas and a reactant gas are independently emitted by using a purge gas and a division member in the substrate processing apparatus according to another modified first embodiment.

FIG. 10 is a partially exploded schematic perspective view of a chamber of a substrate processing apparatus according to a second embodiment.

FIG. 11 is a cross-sectional view taken along line “A-A” of FIG. 10 illustrating a configuration of an emission unit of the substrate processing apparatus according to the second embodiment.

FIG. 12 is a plan cross-sectional view of FIG. 10.

FIG. 13 is a flowchart illustrating a method of processing an exhaust gas according to the present disclosure.

### MODE FOR INVENTION

Hereinafter, an embodiment of a substrate processing apparatus according to the present disclosure will be described in detail with reference to the accompanying drawings.

### First Embodiment

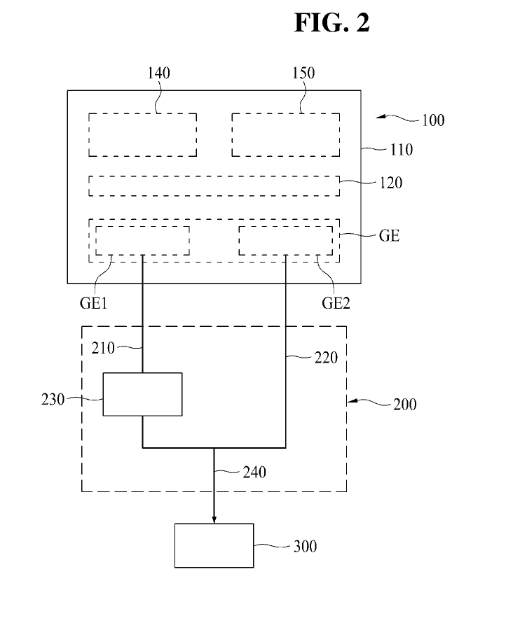

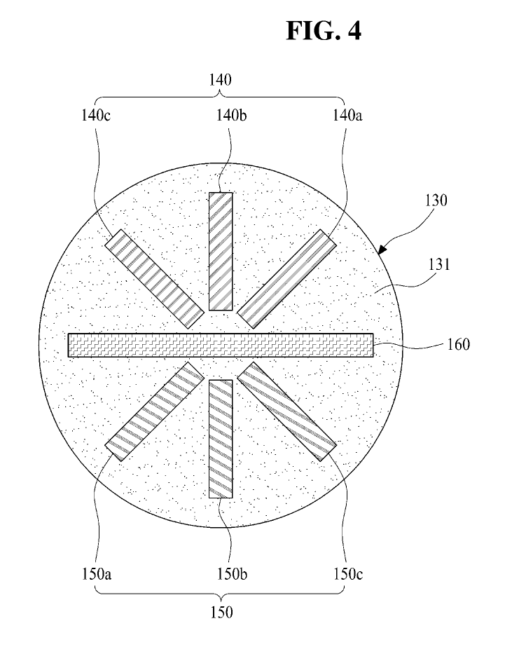

Referring to FIGS. 2 to 4, a substrate processing apparatus according to a first embodiment of the present disclosure may include a gas processing unit 200 for processing an exhaust gas which occurs in a substrate processing unit 100. Before describing the gas processing unit 200, the substrate processing unit 100 will be described below in detail with reference to the accompanying drawings.

The substrate processing unit 100 performs a thin film deposition process for depositing a thin film on a substrate W. For example, a substrate processing apparatus according to the present disclosure may be applied to a plasma enhanced chemical vapor deposition (PECVD) apparatus for forming a thin film by using plasma.

The substrate processing unit 100 activates a source gas and a reactant gas by using plasma and distributes the activated source gas and reactant gas to the substrate W, thereby performing the thin film deposition process on the substrate W. The substrate processing unit 100 respectively distributes the source gas and the reactant gas to a source gas distribution area 120a and a reactant gas distribution area 120b which are spatially separated from each other, thereby performing the thin film deposition process on the substrate W. Therefore, the substrate processing apparatus according to the first embodiment of the present disclosure prevents the source gas and the reactant gas from being mixed with each other in the middle of being distributed, thereby enhancing uniformity of the quality characteristic of a thin film and enhancing controllability of the quality of the thin film. The substrate processing unit 100 distributes the source gas to the source gas distribution area 120a and distributes the reactant gas to the reactant gas distribution area 120b.

The substrate processing unit 100 may include a process chamber 110, a substrate supporting part 120, a chamber lid 130, a source gas distribution unit 140, a reactant gas distribution unit 150, and a purge gas distribution unit 160.

The process chamber 110 provides a process space for a substrate processing process (for example, the thin film deposition process). To this end, the process chamber 110 includes a floor surface and a chamber side wall which is provided vertical to the floor surface to define the process space.

A floor frame 112 may be installed on the floor surface of the process chamber 110. The floor frame 112 includes a guide rail (not shown), which guides a rotation of the substrate supporting part 120, and a first exhaust port 114 and a second exhaust port 114′ for pumping an exhaust gas, existing in the process space, to the outside.

The first exhaust port 114 and the second exhaust port 114′ may be installed at certain intervals in a pumping pipe (not shown) which is disposed adjacent to the chamber side wall in a circular band shape in the floor frame 112, and may communicate with the process space.

The substrate supporting part 120 is installed on an internal floor surface of the process chamber 110, namely, the floor frame 112, and supports at least one substrate W which is loaded from an external substrate loading apparatus (not shown) into the process space through a substrate entrance.

A plurality of substrate positioning areas (not shown) where the substrate W is positioned may be provided on a top of the substrate supporting part 120.

The substrate supporting part 120 may be fixed to or movably installed in the floor frame 112. In this case, if the substrate supporting part 120 is movably installed in the floor frame 112, the substrate supporting part 120 may move (i.e., rotate) in a certain direction (for example, counterclockwise) with respect to a center portion of the floor frame 112.

The chamber lid 130 is installed in an upper portion of the process chamber 110 to seal the process space. Also, the chamber lid 130 detachably supports each of the source gas distribution unit 140, the reactant gas distribution unit 150, and the purge gas distribution unit 160. To this end, the chamber lid 130 includes a lid frame 131 and first to third module mounting parts 133, 135, and 137.

The lid frame 131 is provided in a circular plate shape and covers the upper portion of the process chamber 110, thereby sealing the process space provided by the process chamber 110.

The first module mounting part 133 is provided on one side of the lid frame 131 and detachably supports the source gas distribution unit 140. To this end, the first module mounting part 133 includes a plurality of first module mounting holes 133a which are radially arranged at certain intervals on one side of the lid frame 131 with respect to a center point of the lid frame 131. Each of the plurality of first module mounting holes 133a has a planarly rectangular shape and passes through the lid frame 131.

The second module mounting part 135 is provided on the other side of the lid frame 131 and detachably supports the reactant gas distribution unit 150. To this end, the second module mounting part 135 includes a plurality of second module mounting holes 135a which are radially arranged at certain intervals on the other side of the lid frame 131 with respect to the center point of the lid frame 131. Each of the plurality of second module mounting holes 135a has a planarly rectangular shape and passes through the lid frame 131.

The plurality of first module mounting holes 133a and the plurality of second module mounting holes 135a described above may be provided in the lid frame 131 so as to be symmetric with each other with the third module mounting part 137 therebetween.

The third module mounting part 137 is disposed between the first and second module mounting parts 133 and 135 and is provided in a center portion of the lid frame 131 to detachably support the purge gas distribution unit 160. To this end, the third module mounting part 137 includes a third module mounting hole 137a which is provided in a rectangular shape in the center portion of the lid frame 131.

The third module mounting hole 137a passes through the center portion of the lid frame 131 across a space between the first and second module mounting parts 133 and 135, and thus, is provided in a planarly rectangular shape.

Hereinafter, a substrate processing apparatus according to a first embodiment of the present disclosure will be described on the assumption that the chamber lid 130 includes three first module mounting holes 133a and three second module mounting holes 135a.

The source gas distribution unit 140 is detachably installed in the first module mounting part 133 of the chamber lid 130 and distributes a source gas to a substrate W sequentially moved by the substrate supporting part 120. That is, the source gas distribution unit 140 locally and downward distributes the source gas to each of a plurality of source gas distribution areas 120a which is defined in a space between the chamber lid 130 and the substrate supporting part 120, thereby distributing the source gas to the substrate W passing through a lower portion of each of the plurality of source gas distribution areas 120a according to driving of the substrate supporting part 120. To this end, the source gas distribution unit 140 may include first to third source gas distribution modules 140a to 140c which are detachably mounted on the plurality of first module mounting holes 133a, respectively, and downward distribute the source gas.

Each of the first to third source gas distribution modules 140a to 140c may include a gas distribution frame, a plurality of gas supply holes, and a sealing member.

The gas distribution frame is provided in a box shape to have a bottom opening and is detachably inserted into the first module mounting hole 133a. The gas distribution frame includes a ground plate, which is detachably mounted on the lid frame 131 near the first module mounting hole 133a by a bolt, and a ground side wall which vertically protrudes from a bottom edge of the ground plate to provide a gas distribution space and is inserted into the first module mounting hole 133a. The gas distribution frame is electrically grounded through the lid frame 131 of the chamber lid 130.

A bottom of the gas distribution frame, namely, a bottom of the ground side wall, is disposed on the same line as a bottom of the chamber lid 130 and is spaced apart from a top of the substrate W supported by the substrate supporting part 120 by a certain distance.

The plurality of gas supply holes are provided to pass through a top of the gas distribution frame, namely, the ground plate, and communicates with a gas distribution space provided in the gas distribution frame. The plurality of gas supply holes supply the source gas, supplied from an external gas supply apparatus (not shown), to the gas distribution space, thereby allowing the source gas to be downward distributed to the source gas distribution area 120a through the gas distribution space. The source gas downward distributed from the source gas distribution unit 140 to the source gas distribution area 120a flows in a direction from a center portion of the substrate supporting part 120 to the first exhaust port 114 provided on a side of the substrate supporting part 120.

The source gas includes a main material of a thin film which is to be deposited on the substrate W, and may include a gas such as silicon (Si), titan group element (Ti, Zr, Hf, etc.), aluminum (Al), or the like. For example, the source gas containing silicon (Si) may be silane (SiH₄), disilane (Si₂H₆), trisilane (Si₃H₈), tetraethylorthosilicate (TEOS), dichlorosilane (DCS), hexachlorosilane (HCD), tri-dimethylaminosilane (TriDMAS), trisilylamine (TSA), and/or the like. The source gas may further include a non-reactant gas such as nitrogen (N₂), argon (Ar), xenon (Ze), helium (He), or the like, based on a deposition characteristic of the thin film which is to be deposited on the substrate W.

The reactant gas distribution unit 150 is detachably installed in the second module mounting part 135 of the chamber lid 130 and distributes a reactant gas to the substrate W sequentially moved by the substrate supporting part 120. That is, the reactant gas distribution unit 150 locally and downward distributes the reactant gas to each of a plurality of reactant gas distribution areas 120b which is spatially separated from the source gas distribution area 120a and is defined in a space between the chamber lid 130 and the substrate supporting part 120, thereby distributing the reactant gas to the substrate W passing through a lower portion of each of the plurality of reactant gas distribution areas 120b according to driving of the substrate supporting part 120. To this end, the reactant gas distribution unit 150 may include first to third reactant gas distribution modules 150a to 150c which are detachably mounted on the plurality of second module mounting holes 135a, respectively, and downward distribute the reactant gas.

Except that each of the first to third reactant gas distribution modules 150a, 150b, and 150c is detachably mounted on the second module mounting hole 135a of the chamber lid 130 and downward distributes the reactant gas supplied from the external gas supply apparatus (not shown) to the reactant gas distribution area 120b, each of the first to third reactant gas distribution modules 150a, 150b, and 150c is configured identically to each of the first to third source gas distribution modules 140a, 140b, and 140c. Therefore, the descriptions on the source gas distribution modules 140a, 140b, and 140c are applied to elements of each of the first to third reactant gas distribution modules 150a, 150b, and 150c.

The reactant gas downward distributed from the reactant gas distribution unit 150 to the reactant gas distribution area 120b flows in a direction from the center portion of the substrate supporting part 120 to the second exhaust port 114′ provided on the side of the substrate supporting part 120.

The reactant gas is a gas which includes some materials of a thin film which is to be deposited on the substrate W and forms a final thin film, and may include hydrogen (H₂), nitrogen (N₂), oxygen (O₂), nitrogen dioxide (NO₂), ammonia (NH₃), water (H₂O), ozone (O₃), or the like. The reactant gas may further include a non-reactant gas such as nitrogen (N₂), argon (Ar), xenon (Ze), helium (He), or the like, based on a deposition characteristic of the thin film which is to be deposited on the substrate W.

The source gas or a first exhaust gas where the source gas and the reactant gas are mixed may be emitted through the first exhaust port 114. In this case, a mixing ratio of the source gas and the reactant gas included in the first exhaust gas may be in a state where the source gas is more mixed than the reactant gas. The reactant gas or a second exhaust gas where the reactant gas and the source gas are mixed may be emitted through the second exhaust port 114′. In this case, a mixing ratio of the reactant gas and the source gas included in the second exhaust gas may be in a state where the reactant gas is more mixed than the source gas.

A distribution amount of the source gas distributed from the source gas distribution unit 140 and a distribution amount of the reactant gas distributed from the reactant gas distribution unit 150 may be differently set, and thus, a reaction speed of the source gas and the reactant gas which react with each other on the substrate W may be controlled. In this case, the source gas distribution unit 140 and the reactant gas distribution unit 150 may be configured with gas distribution modules having different areas, or may be configured with a different number of gas distribution modules.

The purge gas distribution unit 160 is detachably installed in the third module mounting part 137 of the chamber lid 130 to downward distribute a purge gas to the process space of the process chamber 110 corresponding to a space between the source gas distribution unit 140 and the reactant gas distribution unit 150, thereby forming a gas barrier for spatially separating the source gas and the reactant gas. That is, the purge gas distribution unit 160 downward distributes the purge gas to the purge gas distribution area 120c defined in a space between the chamber lid 130 and the substrate supporting part 120 to correspond to a space between the source gas distribution area 120a and the reactant gas distribution area 120b, and thus, a gas barrier is formed, thereby decreasing a degree to which the source gas and the reactant gas are mixed with each other in the middle of being downward distributed to the substrate W. Accordingly, the substrate processing unit 100 may spatially separate the source gas distribution area 120a and the reactant gas distribution area 120b. The purge gas may include a non-reactant gas such as nitrogen (N₂), argon (Ar), xenon (Ze), helium (He), or the like.

A purge gas distribution space where the purge gas supplied from a purge gas supply apparatus (not shown) is accommodated is provided in the purge gas distribution unit 160. The purge gas distribution unit 160 supplies the purge gas supplied from the external purge gas supply apparatus (not shown) to the purge gas distribution space, and thus, the purge gas is downward distributed to the purge gas distribution area 120c through the purge gas distribution space to form a gas barrier between the source gas distribution area 120a and the reactant gas distribution area 120b and also allows each of the source gas and the reactant gas respectively distributed to the source gas distribution area 120a and the reactant gas distribution area 120b to flow to the first exhaust port 114 or the second exhaust port 114′ provided on the side of the substrate supporting part 120.

The purge gas distribution unit 160 is installed relatively closer to the substrate supporting part 120 than each of the source gas distribution unit 140 and the reactant gas distribution unit 150 and distributes the purge gas to the purge gas distribution area 120c at a distribution distance (for example, half or less of a distribution distance of the source gas) which is relatively closer than a distribution distance of each of the source gas and the reactant gas to the substrate W, thereby decreasing a degree to which the source gas and the reactant gas are mixed with each other in the middle of being distributed to the substrate W.

The purge gas distribution unit 160 may distribute the purge gas at a distribution pressure which is higher than a distribution pressure of the source gas and the reactant gas.

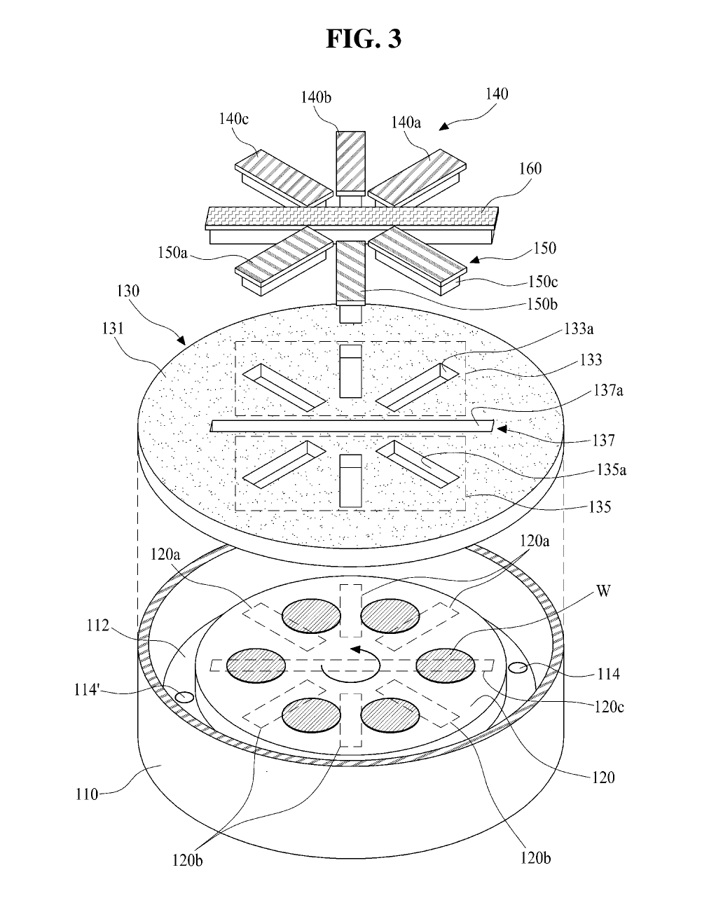

The purge gas distributed from the purge gas distribution unit 160 allows each of the source gas and the reactant gas to flow to the first exhaust port 114 and the second exhaust port 114′ (see FIG. 3), thereby decreasing a degree to which the source gas and the reactant gas are mixed with each other in the middle of being distributed to the substrate W. Accordingly, each of the plurality of substrates W which are moved according to driving of the substrate supporting part 120 is sequentially exposed to each of the source gas and the reactant gas which are separated from each other by the purge gas, and thus, a single-layer or multi-layer thin film is deposited on each substrate W by an atomic layer deposition (ALD) process based on a reaction of the source gas and the reactant gas. Here, the thin film may be a high-k dielectric layer, an insulation layer, a metal layer, or the like.

In a case where the source gas and the reactant gas react with each other, the source gas and the reactant gas may be activated by using plasma and distributed.

A method using plasma is a general method that activates a gas and allows the gas to have an increased chemical reactivity, and the gas is activated to generate a dissociation gas containing ions, free radical, atoms, and molecules. The dissociation gas is used in various industrial and scientific fields including processing of a semiconductor wafer, a solid material such as powder, and the other gas, and a condition where the characteristic and material of an active gas are exposed to a gas is being widely changed depending on fields.

A plasma source, for example, applies an electric potential having a sufficient level to a plasma gas (for example, O₂, N₂, Ar, NF₃, H₂, and He) or a compound of a gas to ionize at least a portion of the gas, thereby generating plasma. The plasma may be generated in various methods including DC discharging, high frequency (RF) discharging, and microwave discharging.

In the substrate processing apparatus according to the first embodiment of the present disclosure, a plasma electrode (not shown) may be additionally provided in the source gas distribution module of the above-described embodiment.

First, a source gas is activated and distributed to a substrate, based on a material of a thin film which is to be deposited on the substrate. Therefore, each of source gas distribution modules according to the present disclosure activates the source gas by using plasma and distributes the activated source gas to the substrate.

In detail, each of the source gas distribution modules according to the present disclosure may further include a plasma electrode which is inserted into and disposed in a gas distribution space.

The plasma electrode is inserted into the gas distribution space, and the plasma electrode generates the plasma from the source gas supplied to the gas distribution space according to a plasma power supplied from a plasma power supply unit (not shown).

The plasma source may be a high frequency power or a radio frequency (RF) power, for example, a low frequency (LF) power, a middle frequency (MF) power, a high frequency (HF) power, or a very high frequency (VHF) power. In this case, the LF power may have a frequency within a range of 3 kHz to 300 kHz, the MF power may have a frequency within a range of 300 kHz to 3 MHz, the HF power may have a frequency within a range of 3 MHz to 30 MHz, and the VHF power may have a frequency within a range of 30 MHz to 300 MHz.

Referring to FIGS. 2 to 4, the gas processing unit 200 is for emitting the source gas and the reactant gas from the substrate processing unit 100 to the outside. The gas processing unit 200 may be coupled to the substrate processing unit 100 and may emit the source gas and the reactant gas, existing in the process chamber 110, to the outside. After the thin film deposition process is completed, the gas processing unit 200 may emit the source gas and the reactant gas from the process chamber 110.

The gas processing unit 200 may independently emit the source gas and the reactant gas from the source gas distribution area 120a and the reactant gas distribution area 120b. Therefore, the substrate processing apparatus according to the first embodiment of the present disclosure decreases a degree to which the source gas and the reactant gas are emitted from the substrate processing unit 100 with being mixed, thereby reducing particles which are generated due to the source gas and the reactant gas being emitted with being mixed.

The gas processing unit 200 may include a first exhaust line 210, a second exhaust line 220, and a third exhaust line 240.

The first exhaust line 210 is for emitting a first exhaust gas from the source gas distribution area 120a. The first exhaust gas includes the reactant gas and the source gas which is more than the reactant gas. The first exhaust gas may include only the source gas without the reactant gas. The first exhaust line 210 may be coupled to the process chamber 110 so as to be connected to the inside of the process chamber 110. The first exhaust line 210 may be coupled to the floor frame 112 of the process chamber 110.

The first exhaust line 210 may be coupled to the process chamber 110 so as to be connected to the first exhaust port 114. The first exhaust gas located in the source gas distribution area 120a may be emitted through the first exhaust port 114 from the process chamber 110 and may be emitted to the outside by moving along the first exhaust line 210.

The first exhaust line 210 may include a first pumping means (not shown), which generates an intake force and an emission force for emitting the first exhaust gas from the source gas distribution area 120a, and a first emission pipe (not shown) that provides a path through which the first exhaust gas moves.

The second exhaust line 220 is for emitting a second exhaust gas from the reactant gas distribution area 120b. The second exhaust gas includes the source gas and the reactant gas which is more than the source gas. The second exhaust gas may include only the reactant gas without the source gas. The second exhaust line 220 may be coupled to the process chamber 110 so as to be connected to the inside of the process chamber 110. The second exhaust line 220 may be coupled to the floor frame 112 of the process chamber 110. The second exhaust line 220 and the first exhaust line 210 may be coupled to the floor frame 112 and may be located at positions spaced apart from each other in the floor frame 112 of the process chamber 110.

The second exhaust line 220 may be coupled to the process chamber 110 so as to be connected to the second exhaust port 114′. The second exhaust gas located in the reactant gas distribution area 120b may be emitted through the second exhaust port 114′ from the process chamber 110 and may be emitted to the outside by moving along the second exhaust line 220.

The second exhaust line 220 may include a second pumping means (not shown), which generates an intake force and an emission force for emitting the second exhaust gas from the reactant gas distribution area 120b, and a second emission pipe (not shown) that provides a path through which the second exhaust gas moves. The second emission pipe and the first emission pipe may respectively include one side, which branch from a separate pipe and are coupled to different positions, and the other sides joined to one pipe. A scrubber may be installed in a portion where the second emission pipe and the first emission pipe are joined.

The gas processing unit 200 may include a catch device 230.

The catch device 230 is for catching and processing the source gas of the first exhaust gas flowing to the first exhaust line 210. The catch device 230 may crack the source gas of the first exhaust gas to catch the source gas of the first exhaust gas. In such a process, the catch device 230 may crack the source gas to a particulate state, thereby preventing particles from being generated in the first exhaust line 210 due to the source gas passing through the first exhaust line 210. Therefore, the substrate processing apparatus according to the first embodiment of the present disclosure prevents particles from being generated from the source gas emitted from the substrate processing unit 100, thereby enhancing exhaust efficiency. Accordingly, by enhancing exhaust efficiency, the substrate processing apparatus according to the first embodiment of the present disclosure can shorten a time taken in exhaust, thereby contributing to shorten a process time of the thin film deposition process.

The catch device 230 may be installed in only the first exhaust line 210 among the first exhaust line 210 and the second exhaust line 220. Therefore, the catch device 230 may perform a process of catching the source gas on only the first exhaust gas among the first exhaust gas and the second exhaust gas emitted from the substrate processing unit 100. Accordingly, the substrate processing apparatus according to the first embodiment of the present disclosure can obtain the following effects.

First, since the substrate processing apparatus according to the first embodiment of the present disclosure is implemented so that the source gas and the reactant gas are independently emitted, a source gas catching process may be performed on only the first exhaust gas which is a main cause of generation of particles. Accordingly, the substrate processing apparatus according to the first embodiment of the present disclosure can reduce the operating cost and the managing cost expended in operating the catch device 230 for preventing generation of particles.

Second, in the substrate processing apparatus according to the first embodiment of the present disclosure, since the catch device 230 performs the source gas catching process on only the first exhaust gas, a gas processing amount of the catch device 230 can be reduced in comparison with a case where the catch device 230 performs the source gas catching process on an exhaust gas where the first exhaust gas and the second exhaust gas are mixed. Accordingly, the substrate processing apparatus according to the first embodiment of the present disclosure can decrease a capacity of the catch device 230, and thus, the manufacturing cost of the catch device 230 can be reduced, and moreover, the catch device 230 can be miniaturized.

The catch device 230 may include a plasma trap.

By using plasma, the plasma trap can prevent particles from being generated from the source gas emitted from the substrate processing unit 100. The plasma trap cracks the source gas emitted from the substrate processing unit 100 by using the plasma, thereby preventing generation of particles. For example, if the source gas is silicon hexachloride (Si₂Cl₆), the plasma trap cracks silicon hexachloride into silicon (Si) and chlorine (Cl) by using the plasma, thereby preventing generation of particles.

Here, the substrate processing unit 100 may perform the thin film deposition process by using the reactant gas from which particles are not generated in an emission process. For example, the reactant gas may be at least one of hydrogen (H₂), nitrogen (N₂), oxygen (O₂), nitrogen dioxide (NO₂), ammonia (NH₃), water (H₂O), and ozone (O₃). Therefore, the substrate processing apparatus according to the first embodiment of the present disclosure can prevent particles from being generated from the reactant gas, even without the catch device 230 being installed in the second exhaust line 220. Also, the source gas can be included even in the second exhaust gas passing through the second exhaust line 220, but since an amount of the source gas is small, smooth exhaust based on the second exhaust line 220 may be implemented even without the catch device 230.

The third exhaust line 240 is connected to an exhaust pump 300 so as to exhaust the first exhaust gas, passing through the catch device 230 via the first exhaust line 210, and the second exhaust gas passing through the second exhaust line 220. Therefore, the first exhaust gas flowing to the first exhaust line 210 is transferred to the exhaust pump 300 via the third exhaust line 240 with the first exhaust gas being combined with the second exhaust gas which flows to the second exhaust line 220 after the source gas passes through the catch device 230 and is caught.

The third exhaust line 240 may be installed so that one side connects the first exhaust line 210 and the second exhaust line 220 to one pipe and the other side is connected to the exhaust pump 300.

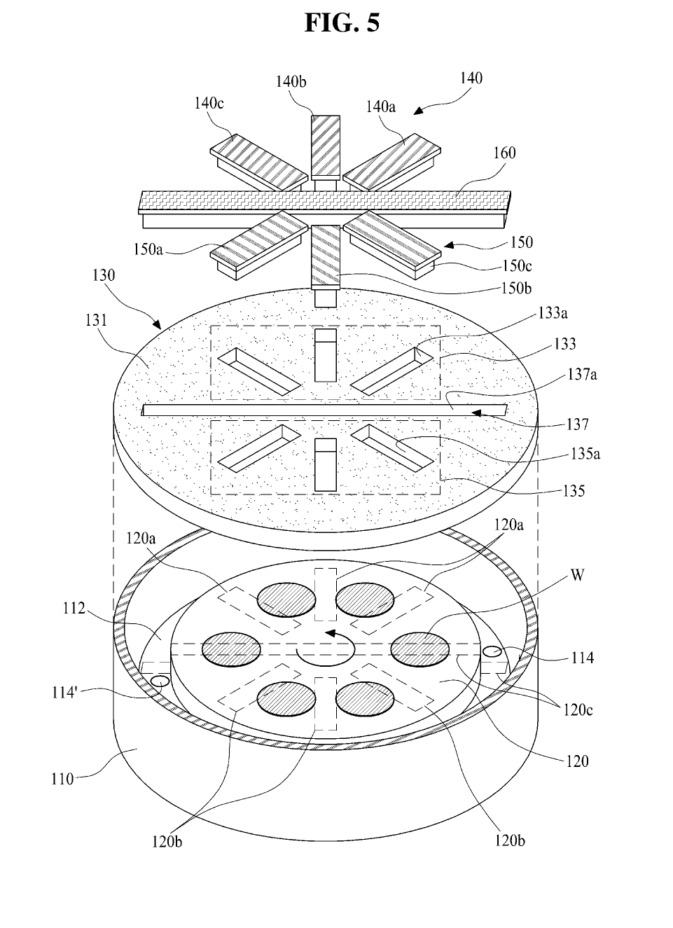

Referring to FIGS. 2 to 6, the substrate processing apparatus according to the first embodiment of the present disclosure may spatially separate a gas emission area into a first gas emission area and a second gas emission area by using the purge gas.

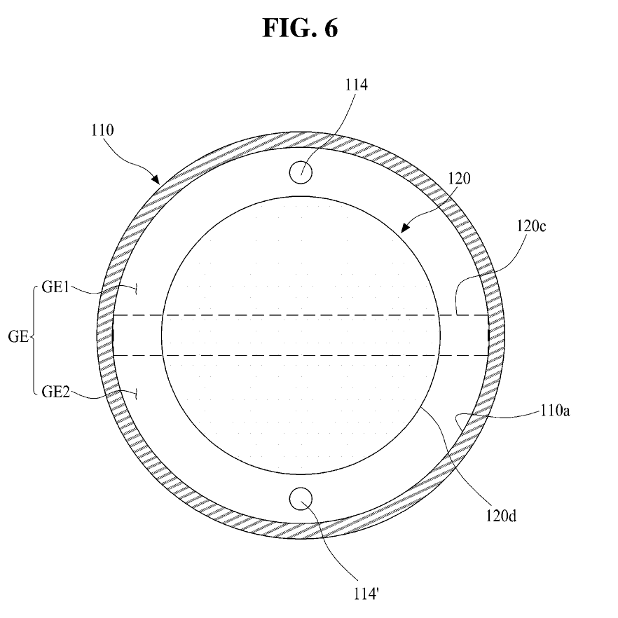

To this end, the purge gas distribution unit 160 may additionally distribute the purge gas to the gas emission area GE (illustrated in FIG. 6). The gas emission area GE is disposed between an inner circumference surface 110a of the process chamber 110 and an outer circumference surface 120d of the substrate supporting part 120. The purge gas distribution unit 160 may additionally distribute the purge gas to the gas emission area GE to spatially separate the gas emission area GE into a first gas emission area GE1 and a second gas emission area GE2. The first exhaust line 210 is connected to the first gas emission area GE1. The second exhaust line 220 is connected to the second gas emission area GE2.

Therefore, the first exhaust gas is emitted to the outside of the process chamber 110 through the first exhaust line 210 via the first gas emission area GE1. The second exhaust gas is emitted to the outside of the process chamber 110 through the second exhaust line 220 via the second gas emission area GE2.

Therefore, the substrate processing apparatus according to the first embodiment of the present disclosure prevents the first exhaust gas and the second exhaust gas from being mixed with each other in the middle of being emitted, thereby increasing a blocking force for reducing particles generated from the source gas.

The purge gas distribution unit 160 may be implemented to distribute the purge gas to the purge gas distribution area 120c greater than an area corresponding to a diameter of the substrate supporting part 120, in order to additionally distribute the purge gas to the gas emission area GE. The purge gas distribution unit 160 may be implemented to distribute the purge gas to the purge gas distribution area 120c corresponding to an internal diameter of the process chamber 110.

The first exhaust port 114 may be disposed in the first gas emission area GE1. The first exhaust port 114 may be provided in the process chamber 110 and may be disposed in the first gas emission area GE1. The first exhaust line 210 may be connected to the first gas emission area GE1 through the first exhaust port 114.

The second exhaust port 114′ may be disposed in the second gas emission area GE2. The second exhaust port 114′ may be provided in the process chamber 110 and may be disposed in the second gas emission area GE2. The second exhaust line 220 may be connected to the second gas emission area GE2 through the second exhaust port 114′.

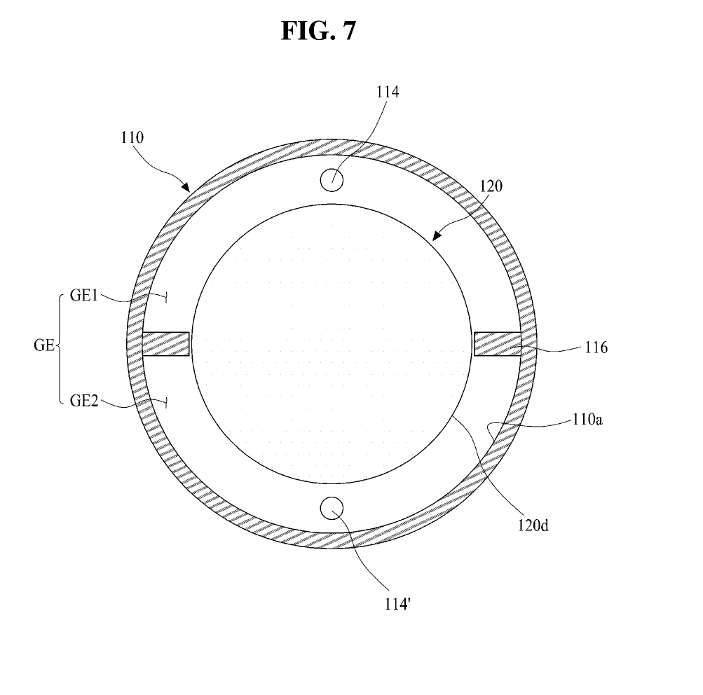

Referring to FIGS. 2 to 7, a substrate processing apparatus according to a modified first embodiment of the present disclosure may be implemented to spatially separate a gas emission area into a first gas emission area and a second gas emission area by using a division member.

To this end, the substrate processing unit 100 may include a division member 116 disposed in the gas emission area GE. The division member 116 may be provided to protrude in a direct from the inner circumference surface 110a of the process chamber 110 to the outer circumference surface 120d of the substrate supporting part 120. Accordingly, the division member 116 may spatially separate the gas emission area GE into the first gas emission area GE1 and the second gas emission area GE2.

Therefore, by using the division member 116 without the purge gas, the substrate processing apparatus according to the modified first embodiment of the present disclosure can prevent the first exhaust gas and the second exhaust gas from being mixed with each other in the middle of being emitted, thereby decreasing the operating cost in comparison with a case using the purge gas.

The division member 116 may be coupled to the process chamber 110 so that one side is coupled to the inner circumference surface 110a of the process chamber 110 and the other side contacts the outer circumference surface 120d of the substrate supporting part 120. The division member 116 may be provided in a rectangular parallelepiped shape, but may be provided in another shape enabling the gas emission area GE to be spatially separated without being limited thereto. The substrate processing unit 100 may include a plurality of the division members 116.

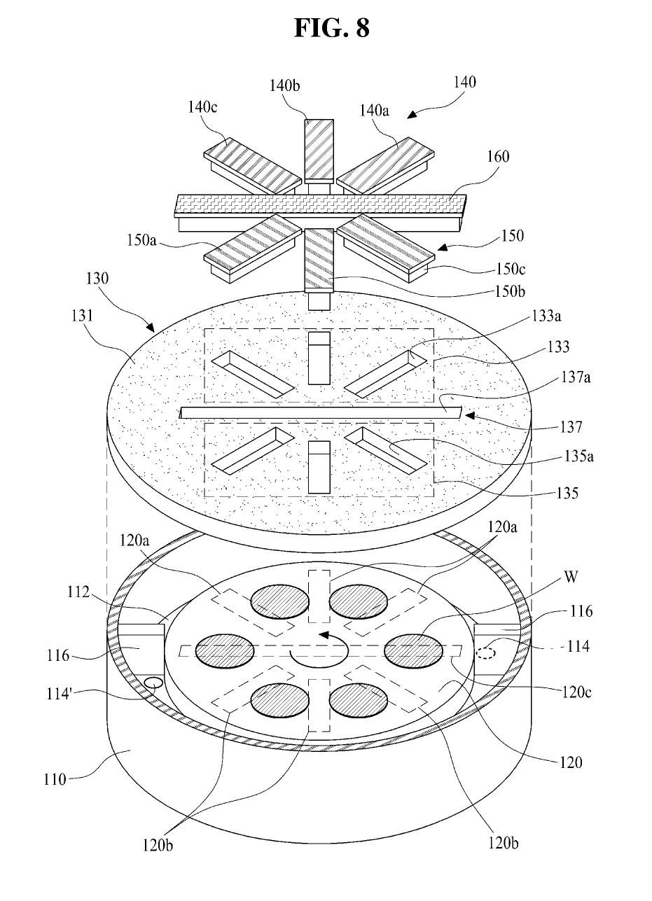

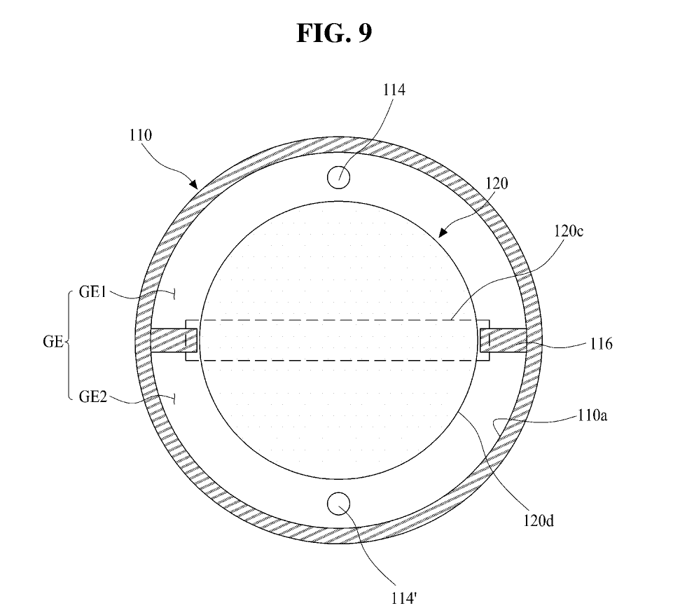

Referring to FIGS. 8 and 9, a substrate processing apparatus according to another modified first embodiment of the present disclosure may be implemented to spatially separate a gas emission area into a first gas emission area and a second gas emission area by using both the purge gas and a division member.

To this end, the substrate processing unit 100 may include a division member 116 that is provided to protrude in a direction from the inner circumference surface 110a of the process chamber 110 to the outer circumference surface 120d of the substrate supporting part 120. The purge gas distribution unit 160 may distribute the purge gas to a space between the outer circumference surface 120d of the substrate supporting part 120 and the division member 116. Therefore, the gas emission area GE may be spatially separated into the first gas emission area GE1 and the second gas emission area GE2 by a combination of the division member 116 and the purge gas.

Therefore, the substrate processing apparatus according to another modified first embodiment of the present disclosure can obtain the following effects.

First, the substrate processing apparatus according to another modified first embodiment of the present disclosure can reduce a size of an area to which the purge gas distribution unit 160 distributes the purge gas, in comparison with a case using only the above-described purge gas. This is because it is not required to distribute the purge gas to a portion where the division member 116 spatially separates the gas emission area GE. Therefore, the substrate processing apparatus according to another modified first embodiment of the present disclosure can prevent the first exhaust gas and the second exhaust gas from being mixed with each other in the middle of being emitted, and moreover, can reduce the operating cost which is expended when the first exhaust gas and the second exhaust gas are mixed with each other.

Second, the substrate processing apparatus according to another modified first embodiment of the present disclosure may be implemented in order for the division member 116 not to contact the outer circumference surface 120d of the substrate supporting part 120, in comparison with a case using only the above-described division member. This is because the division member 116 and the outer circumference surface 120d of the substrate supporting part 120 are spatially separated from each other by the purge gas. Therefore, the substrate processing apparatus according to another modified first embodiment of the present disclosure can prevent wear, damage, and/or the like from occurring due to friction when the division member 116 contacts the outer circumference surface 120d of the substrate supporting part 120, thereby decreasing the managing cost of the division member 116 and the substrate supporting part 120.

The purge gas distribution unit 160 may be implemented to distribute the purge gas to the purge gas distribution area 120c which is greater than a diameter of the substrate supporting part 120 and less than an internal diameter of the process chamber 110, in order to additionally distribute the purge gas to the gas emission area GE.

### Second Embodiment

First, a substrate processing apparatus according to a second embodiment of the present disclosure will be described.

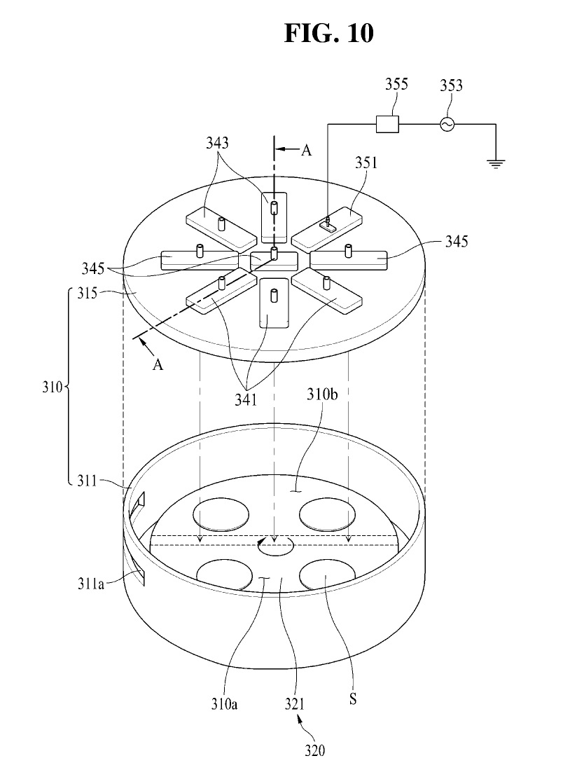

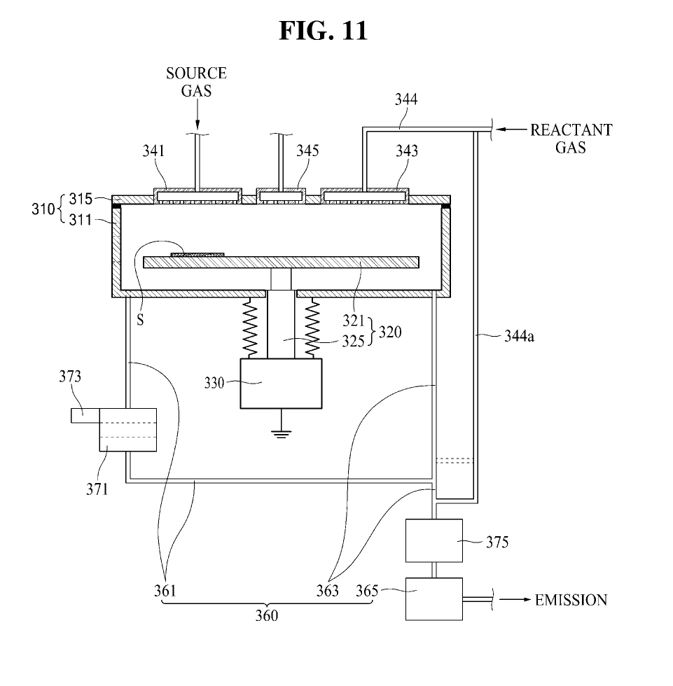

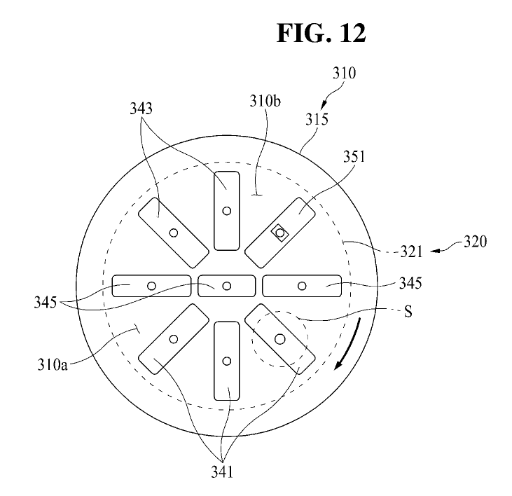

FIG. 10 is a partially exploded schematic perspective view of a chamber of a substrate processing apparatus according to a second embodiment of the present disclosure, FIG. 11 is a cross-sectional view taken along line “A-A” of FIG. 10 illustrating a configuration of an emission unit of the substrate processing apparatus according to the second embodiment of the present disclosure, and FIG. 12 is a plan cross-sectional view of FIG. 10.

Processing of a substrate S may include forming of a pattern-shaped thin film, such as an electrode or a dielectric layer including metal oxide, on the substrate S.

As illustrated, the substrate processing apparatus according to the second embodiment of the present disclosure may include a chamber 310 where a space, which the substrate S such as a silicon wafer or glass is inserted into and processed in, is provided. The chamber 310 may include a body 311, of which an upper end surface is opened and which is located on a relatively lower side, and a lid 315 which is coupled to the opened upper end surface of the body 311 and is located on a relatively upper side.

Since the body 311 and the lid 315 are coupled to each other and are respectively located on the lower side and the upper side, a bottom of the chamber 310 corresponds to a bottom of the body 311, and a top of the chamber 310 corresponds to the lid 315.

A substrate entrance 311a, through which the substrate S is loaded into the chamber 310 or is unloaded from the chamber 310 to the outside, may be provided in a side surface of the chamber 310, and the substrate entrance 311a may be opened or closed by an opening/closing unit (not shown).

A substrate supporting part 320, which the substrate S is mounted on and supported by, may be installed on an internal bottom of the chamber 310. The substrate supporting part 320 may include a susceptor 321, which is located in the chamber 310 and includes a top on which the substrate S is mounted, and a supporting shaft 325 which is coupled to a bottom of the susceptor 321 and includes a lower end exposed to outside a bottom of the chamber 310.

A heating means (not shown) such as a heater for heating the substrate S may be installed in a portion of the susceptor 321 which the substrate S is mounted on and supported by, and a plurality of substrates may be radially mounted on and supported by a top of the susceptor 321. Also, a sealing module such as bellows sealing a space between the chamber 310 and the supporting shaft 325 may be installed in a portion of the supporting shaft 325 outside the chamber 310.

A portion of the supporting shaft 325 exposed to outside the chamber 310 may be connected to a driver 330, and the driver 330 may raise and lower or rotate a substrate supporting part 320. That is, the driver 330 may raise and lower or rotate the supporting shaft 325 to raise and lower or rotate the susceptor 321. Therefore, the substrate S mounted on the susceptor 321 may be raised and lowered, or may revolve about the supporting shaft 325.

In order to deposit a thin film on the substrate S, a process gas should be supplied to the chamber 310. The process gas may include a source gas and a reactant gas, the source gas may be a material deposited on the substrate S, and the reactant gas may be a material which helps the source gas to be stably deposited on the substrate S.

In order to distribute the source gas and the reactant gas to the substrate S which is mounted on and supported by the substrate supporting part 320 and rotates, a first distribution unit 341 for distributing the source gas and a second distribution unit 343 for distributing the reactant gas may each be installed on the top of the chamber 310. The first distribution unit 341 may distribute the source gas to a first area 310a of the chamber 310, and the second distribution unit 343 may distribute the reactant gas to a second area 310b of the chamber 310. In this case, the source gas may be zirconium (Zr) bonded to amine, and the reactant gas may be O₃.

Furthermore, a third distribution unit 345 that distributes a purge gas, which is an inert gas such as argon (Ar) or the like, to the substrate S may be installed on the top of the chamber 310 between the first distribution unit 341 and the second distribution unit 343.

The third distribution unit 345 may distribute the purge gas to a space between the first area 310a and the second area 310b to spatially separate the space between the first area 310a and the second area 310b. Therefore, the source gas which is distributed from the first distribution unit 341 and exists in the first area 310a is prevented from being mixed with the reactant gas which is distributed from the second distribution unit 343 and exists in the second area 310b. That is, the purge gas performs a function of an air curtain.

The first distribution unit 341 may be provided in plurality, and the plurality of first distribution units 341 may be arranged at certain intervals. The second distribution unit 343 may be provided in plurality, and the plurality of second distribution units 343 may be arranged at certain intervals. Therefore, when the substrate S is located under the first distribution unit 341 and the second distribution unit 343 according to the substrate supporting part 320 rotating, the source gas and the reactant gas are sequentially distributed to the substrate S, and a thin film is deposited on the substrate S through a reaction between the source gas and the reactant gas.

Each of the first distribution unit 341 and the second distribution unit 343 may be provided as a showerhead or the like. In order to uniformly distribute the source gas and the reactant gas to the substrate S, a plurality of distribution holes may be provided in a bottom of each of the first distribution unit 341 and the second distribution unit 343. Also, in order for the source gas and the reactant gas to be distributed to a whole surface of the substrate S, it is preferable that a radius-direction length of each of the first distribution unit 341 and the second distribution unit 343 is longer than a diameter of the substrate S, with respect to a center of the substrate supporting part 320.

A plasma generator 351, which generates the reactant gas in a plasma state or generates a separate inflow gas in the plasma state, may be installed on the top of the chamber 310 where the second distribution unit 343 is disposed. Also, a power device 353 for applying a radio frequency (RF) power or the like to the plasma generator 351 and a matcher 355 for matching impedance may be installed outside the chamber 310. The power device 353 may be grounded, and the plasma generator 351 may be grounded by using the power device 353.

Only some of the source gas supplied to the chamber 310 is deposited on the substrate S, and only some of the reactant gas reacts with the source gas. Therefore, the other source gas which is not deposited on the substrate S, the other reactant gas which does not react with the source gas, and byproducts occurring in a deposition process should be emitted to the outside of the chamber 310.

The substrate processing apparatus according to the second embodiment of the present disclosure may include an emission unit 360 for emitting a source gas which is not deposited on the substrate S, a reactant gas which does not react with the source gas, and byproducts to the outside of the chamber 310. The emission unit 360 may include a first exhaust line 361, a second exhaust line 363, and an exhaust pump 365.

One end of the first exhaust line 361 may communicate with the bottom of the chamber 310 disposed on a lower side of the first area 310a, and the other end may communicate with the exhaust pump 365. Also, a first collection unit 371 to be described below may communicate with the first exhaust line 361. Therefore, the first exhaust line 361 may emit a source gas, which is not deposited on the substrate S, of the source gas distributed to the first area 310a and byproducts to the outside of the chamber 310, and thus, the emitted source gas and byproducts may flow into the first collection unit 371.

One end of the second exhaust line 363 may communicate with the bottom of the chamber 310 disposed on a lower side of the second area 310b, and the other end may communicate with the exhaust pump 365. In this case, a second collection unit 375 to be described below may communicate with the second exhaust line 363. The other end of the first exhaust line 361 may communicate with the other end of the second exhaust line 363 and may communicate with the exhaust pump 365. Therefore, a source gas and byproducts, which are not collected by the first collection unit 371, of the source gas and the byproducts emitted from the chamber 310 may flow into the second collection unit 375 and may be processed again.

The exhaust pump 365 may be provided as a vacuum pump or the like, and as described above, may communicate with the other end of the second exhaust line 363. Therefore, when the exhaust pump 363 is driven, byproducts and a source gas which is not deposited on the substrate S in the first area 310a flow into the first collection unit 371 through the first exhaust line 361, byproducts and a reactant gas which does not react with the source gas in the second area 310b flow into the second collection unit 375 through the second exhaust line 363, and byproducts and a source gas which are not collected by the first collection unit 371 flow into the second collection unit 375.

When the source gas emitted from the chamber 310 directly flows into the exhaust pump 365, the source gas may react with heat occurring in the exhaust pump 365 or the reactant gas flowing to the exhaust pump 365 through the second exhaust line 363, and thus, may be deposited on an inner surface of the exhaust pump 365. Therefore, the exhaust pump 365 can be damaged by the source gas deposited on the exhaust pump 365. Also, depending on the case, the source gas can be exploded by the heat which occurs in the exhaust pump 365.

In order to prevent such a problem, the substrate processing apparatus according to the second embodiment of the present disclosure may include the above-described first collection unit 371 for collecting a source gas and byproducts, flowing into the first exhaust line 361, in a powder state.

A plurality of spaces which are vertically divided may be provided in the first collection unit 371, and a source gas and byproducts may pass through the spaces in the order of an uppermost space→a middle space→a lowermost space. Therefore, a source gas and byproducts flowing into the first collection unit 371 may be collected by the first collection unit 371 in a powder state, and a source gas and byproducts which are not collected by the first collection unit 371 may flow into the second collection unit 375 through the second exhaust line 363.

A plasma generator 373 may be installed in an uppermost space of the first collection unit 371, in order for the first collection unit 371 to collect the source gas and the byproducts in a powder state. The plasma generator 373 may generate oxygen (O₂), which flows in, as plasma. Therefore, a source gas and byproducts emitted from the chamber 310 may react with oxygen plasma and may be collected in a powder state.

In the substrate processing apparatus according to the second embodiment of the present disclosure, a source gas and byproducts emitted without being collected by the first collection unit 371 flow into the second collection unit 375. Therefore, the source gas and the byproducts which are not collected by the first collection unit 371 and a reactant gas and byproducts emitted from the second area 310b may be processed in the second collection unit 375 together.

Moreover, the source gas and the byproducts which are not collected by the first collection unit 371 and the reactant gas and the byproducts emitted from the second area 310b may be collected by the second collection unit 375 in a powder state, and O₃ supplied to the second distribution unit 343 may be branched and supplied to the second collection unit 375 in order for the second collection unit 375 to collect the source gas, the reactant gas, and the byproducts in a powder state.

To provide a detailed description, a reactant gas supply line 344 for supplying O₃, which is a reactant gas, to the second distribution unit 343 may be installed, and a reactant gas branch line 344a for supplying O₃ to the second collection unit 375 may branch from and may be provided on one side of the reactant gas supply line 344. Therefore, the source gas and the byproducts which are not collected by the first collection unit 371 and the reactant gas and the byproducts emitted from the second area 310b may react with O₃ and may be collected by the second collection unit 375 in a powder state.

The branch line 344a, as illustrated as a solid line in FIG. 11, may communicate with a portion of the second exhaust line 363 between the other end of the first exhaust line 361 and the exhaust pump 365 and, as illustrated as a dotted line in FIG. 11, may communicate with a portion of the second exhaust line 363 between the other end of the first exhaust line 361 and the chamber 310.

As a result obtained by analyzing an absorptance based on wavenumbers of powders collected by the first collection unit 371 and the second collection unit 375, when the plasma generator 373 generates oxygen plasma and supplies the oxygen plasma to the first collection unit 371, amine bonded to zirconium which is a source gas has not been detected, but when the oxygen plasma is not supplied to the first collection unit 371, amine has been detected. That is, it can be seen that when a gas flowing into the first collection unit 371 is processed by using the oxygen plasma, amine bonded to zirconium is cracked.

An amine-bonded source gas and byproducts emitted from the chamber 310 are collected by the first collection unit 371 and the second collection unit 375 twice, and a reactant gas and byproducts emitted from the chamber 310 are collected by the second collection unit 375, whereby the source gas, the reactant gas, and the byproducts emitted from the chamber 310 are almost collected. Therefore, most of gases emitted from the second collection unit 375 are a purge gas, and some byproducts may be included in the emitted gases.

Hereinafter, an embodiment of a method of processing an exhaust gas according to the present disclosure will be described.

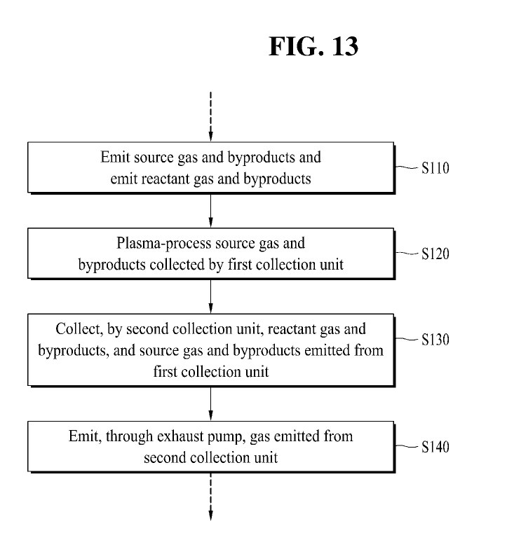

FIG. 13 is a flowchart illustrating a method of processing an exhaust gas according to the present disclosure.

The method of processing the exhaust gas according to the present disclosure may be performed by the substrate processing apparatus according to the present disclosure described above. Hereinafter, a case where the method of processing the exhaust gas according to the present disclosure is performed by the substrate processing apparatus according to the second embodiment of the present disclosure described above will be described with reference to FIGS. 10 to 13.

First, the substrate S is mounted on the substrate supporting part 320, and then, the purge gas is distributed through the third distribution unit 345 while rotating the substrate supporting part 320. Therefore, the first area 310a and the second area 310b of the chamber 310 are spatially divided by the purge gas.

Subsequently, zirconium (Zr) which is the source gas is distributed to the first area 310a of the chamber 310, and O₃ which is the reactant gas is distributed to the second area 310b of the chamber 310, thereby depositing a thin film, such as a high-k dielectric layer or the like, on the substrate S. Therefore, some of the source gas distributed to the first area 310a of the chamber 310 is deposited on the substrate S, and the other source gas is not deposited on the substrate S. Furthermore, some of the reactant gas distributed to the second area 310b of the chamber 310 reacts with the source gas, and the other reactant gas does not react with the source gas.

Therefore, a source gas which is not deposited on the substrate S and byproducts occurring in the deposition process exist in the first area 310a of the chamber 310, and a reactant gas which does not react with the source gas and byproducts occurring in the deposition process exist in the second area 310b of the chamber 310.

Therefore, as illustrated in FIG. 13, in operation S110, by driving the exhaust pump 365, a source gas which is distributed to the first area 310a of the chamber 310 but is not deposited on the substrate S and byproducts occurring in the deposition process may be extracted and emitted to the first exhaust line 361, and a reactant gas which is distributed to the second area 310b of the chamber 310 but does not react with the source gas and byproducts occurring in the deposition process may be extracted and emitted to the second exhaust line 363.

When the source gas and the byproducts flowing into the first exhaust line 361 and the reactant gas and the byproducts flowing into the second exhaust line 363 flow into the exhaust pump 365 as-is and are emitted, the source gas and/or the like is deposited on an inner surface of the exhaust pump 365, and for this reason, the exhaust pump 365 can be damaged.

In order to prevent the damage, in operation S120, the source gas and the byproducts may be processed in the first collection unit 371 which is installed to communicate with the first exhaust line 361. The first collection unit 371 may process the source gas and the byproducts by using oxygen (O₂) plasma. Therefore, the source gas and the byproducts flowing into the first collection unit 371 may be collected by the oxygen plasma in a powder state.

Most of the source gas and the byproducts flowing into the first collection unit 371 may be collected by the first collection unit 371, or some may not be collected by the first collection unit 371.

Subsequently, in operation S130, a source gas and byproducts which are not collected by the first collection unit 371 and a reactant and byproducts emitted from the second area 310b of the chamber 310 may be collected by the second collection unit 375, and by using O₃ which is a reactant gas, the second collection unit 375 may collect the source gas, the reactant gas, and the byproducts which flow in.

Therefore, the source gas, the reactant gas, and the byproducts flowing into the second collection unit 375 may be collected by O₃ in a powder state.

Moreover, in operation S140, gases emitted without being collected by the second collection unit 375 may pass through the inside of the exhaust pump 365 and may be emitted. In this case, most of the gases emitted from the exhaust pump 365 may be a purge gas.

In the substrate processing apparatus and the method of processing the exhaust gas according to the second embodiment of the present disclosure, a source gas and byproducts emitted from the chamber 310 are processed with plasma and are collected by the first collection unit 371 in a powder state. Also, a source gas and byproducts emitted without being collected by the first collection unit 371 and a reactant gas and byproducts emitted from the chamber 310 are collected by the second collection unit 375 in a powder state. Therefore, the source gas is prevented from being deposited on the exhaust pump 365, thereby preventing the exhaust pump 365 from being damaged.

Moreover, since the source gas is not deposited on the exhaust pump 365, a risk of explosion of the source gas caused by heat occurring in the exhaust pump 365 is completely removed.

In the substrate processing apparatus according to the second embodiment of the present disclosure, a distribution area of the chamber 310 to which a source gas is distributed may differ from a distribution area of the chamber 310 to which a reactant gas is distributed, or the source gas and the reactant gas may be distributed with a time difference. Also, the second collection unit 375 may collect a mixed gas of an exhaust gas which has been plasma-activated by passing through the first collection unit 371, and the second collection unit 375 may collect a gas in a non-plasma manner.

Those skilled in the art can understand that the present disclosure can be embodied in another detailed form without changing the technical spirit or the essential features. Therefore, it should be understood that the embodiments described above are exemplary from every aspect and are not restrictive. It should be construed that the scope of the present disclosure is defined by the below-described claims instead of the detailed description, and the meanings and scope of the claims and all variations or modified forms inferred from their equivalent concepts are included in the scope of the present disclosure.

1. A substrate processing apparatus to which a source gas and a reactant gas are distributed, the substrate processing apparatus comprising:
a first exhaust line exhausting a first exhaust gas including the reactant gas and the source gas which is more than the reactant gas;
a second exhaust line exhausting a second exhaust gas including the source gas and the reactant gas which is more than the source gas;
a catch device installed in the first exhaust line; and
a third exhaust line connected to an exhaust pump to exhaust the first exhaust gas passing through the catch device and the second exhaust gas passing through the second exhaust line,
wherein the catch device catches the source gas flowing into the first exhaust line.

2. The substrate processing apparatus of claim 1, wherein the catch device comprises a plasma trap for preventing generation of particles.

3. The substrate processing apparatus of claim 1, wherein the reactant gas is at least one of hydrogen (H₂), nitrogen (N₂), oxygen (O₂), nitrogen dioxide (NO₂), ammonia (NH₃), water (H₂O), and ozone (O₃).

4. The substrate processing apparatus of claim 1, comprising a substrate processing unit performing a thin film deposition process of respectively distributing the source gas and the reactant gas to a source gas distribution area and a reactant gas distribution area, which are spatially separated from each other, to deposit a thin film on a substrate.

5. The substrate processing apparatus of claim 4, wherein
the substrate processing unit comprises a process chamber providing a process space, a substrate supporting part installed in the process chamber to support at least one substrate, and a purge gas distribution unit distributing a purge gas to a space between the source gas distribution area and the reactant gas distribution area to spatially separate the source gas distribution area and the reactant gas distribution area,
the purge gas distribution unit additionally distributes the purge gas to a gas emission area between an inner circumference surface of the process chamber and an outer circumference surface of the substrate supporting part to spatially separate the gas emission area into a first gas emission area and a second gas emission area,
the first exhaust line is coupled to the process chamber and is connected to the first gas emission area, and
the second exhaust line is coupled to the process chamber and is connected to the second gas emission area.

6. The substrate processing apparatus of claim 5, wherein
the process chamber comprises a first exhaust port provided in the first gas emission area and a second exhaust port provided in the second gas emission area,
the first exhaust line is connected to the first gas emission area through the first exhaust port, and
the second exhaust line is connected to the second gas emission area through the second exhaust port.

7. The substrate processing apparatus of claim 5, wherein
the substrate processing unit comprises a division member provided to protrude in a direction from the inner circumference surface of the process chamber to the outer circumference surface of the substrate supporting part, and disposed in the gas emission area, and
the purge gas distribution unit distributes the purge gas to a space between the outer circumference surface of the substrate supporting part and the division member to spatially separate the first gas emission area and the second gas emission area.

8. The substrate processing apparatus of claim 5, wherein the purge gas distribution unit distributes the purge gas at a distribution pressure which is higher than a distribution pressure of the source gas and the reactant gas.

9. A substrate processing apparatus, where an area of a chamber to which a source gas is distributed differs from an area of the chamber to which a reactant gas is distributed, or the source gas and the reactant gas are distributed with a time difference, the substrate processing apparatus comprising:
a first exhaust line emitting the source gas from the chamber;
a second exhaust line spaced apart from the first exhaust line to emit the reactant gas from the chamber;
a first collection unit collecting a gas including the source gas flowing into the first exhaust line to process the collected gas with plasma; and
a second collection unit collecting a gas including an exhaust gas flowing into the second exhaust line.

10. The substrate processing apparatus of claim 9, wherein oxygen (O₂) plasma flows into the first collection unit.

11. The substrate processing apparatus of claim 9, wherein the source gas is zirconium (Zr) bonded to amine, and the reactant gas is ozone (O₃).

12. (canceled)

13. (canceled)

14. (canceled)

15. (canceled)

16. (canceled)

17. (canceled)

18. A substrate processing apparatus, where an area of a chamber to which a source gas is distributed differs from an area of the chamber to which a reactant gas is distributed, or the source gas and the reactant gas are distributed with a time difference, the substrate processing apparatus comprising:
a first exhaust line connected to the chamber;
a second exhaust line connected to and spaced apart from the first exhaust line; and
a second collection unit having a non-plasma manner, wherein a first exhaust gas plasma-activated and a second exhaust gas passing through the second exhaust line are mixed and flow into the second collection unit.

19. (canceled)

20. The substrate processing apparatus of claim 19, wherein
the source gas is zirconium (Zr) bonded to amine, and
the reactant gas is ozone (O₃).

21. The substrate processing apparatus of claim 9, wherein the second collection unit further collects a mixed gas of an exhaust gas which has been plasma-activated by passing through the first collection unit.

22. The substrate processing apparatus of claim 9, wherein a second collection unit further collects a gas passing through the first collection unit.

23. The substrate processing apparatus of claim 2, wherein the reactant gas is at least one of hydrogen (H₂), nitrogen (N₂), oxygen (O₂), nitrogen dioxide (NO₂), ammonia (NH₃), water (H₂O), and ozone (O₃).

24. The substrate processing apparatus of claim 18,
wherein the first exhaust gas plasma-activated in the first exhaust line and the second exhaust gas passing through the second exhaust line are mixed and flow into the second collection unit.

25. The substrate processing apparatus of claim 24, wherein oxygen (O₂) plasma flows into the first exhaust line.

26. The substrate processing apparatus of claim 18, further comprising a plasma generator provided in the first exhaust line,
wherein the first exhaust gas passing through the plasma generator and the second exhaust gas passing through the second exhaust line are mixed and flow into the second collection unit.

27. The substrate processing apparatus of claim 26, wherein the plasma generator generates oxygen (O₂) as plasma.
